(19) United States
(12) Patent Application Publication
(10) Pub. No.: US 2025/0372943 A1
(43) Pub. Date: Dec. 4, 2025

(54) LASER ASSEMBLY HAVING ALIGNMENT MOUNTS FOR HERRIOTT CELL

(71) Applicant: SeekOps Inc., Austin, TX (US)

(72) Inventors: Garrett Niall John, Escondido, CA (US); James Rutherford, Cypress, TX (US); Brendan James Smith, Lakeway, TX (US)

(21) Appl. No.: 18/870,375

(22) PCT Filed: May 31, 2023
(86) PCT No.: PCT/US23/23933

§ 371 Date: Nov. 27, 2024

Related U.S. Application Data
(60) Provisional application No. 63/347,439, filed on May 31, 2022.

(51) Int. Cl. H01S 5/0239; H01S 5/00

(52) U.S. Cl. CPC H01S 5/0239; H01S 5/0014

(57) ABSTRACT

Systems, devices, and methods for a laser assembly including a first mirror defining at least one groove extending radially outwardly from a first center hole towards an outer edge of the first mirror and a second mirror having at least one slot extending radially outwardly from a second center hole towards an outer edge of the second mirror; a center rod having a first end portion configured to support the first mirror and defining at least one first keyway; a first mount configured to engage the first mirror and the first end portion; where the first mount has at least one key adapted to engage at least one first keyway and a second mount has at least one protrusion adapted to engage with at least one second keyway.

### CROSS-REFERENCE TO RELATED APPLICATIONS

This application is a 35 U.S.C § 371 National Stage Entry of International Application No. PCT/US2023/023933, filed May 31, 2023, which claims the priority benefit of U.S. Provisional Patent Application Ser. No. 63/347,439 filed May 31, 2022, all of which are hereby incorporated herein by reference in their entirety for all purposes.

### FIELD OF ENDEAVOR

The invention relates to a laser assembly, and more particularly to aligning mirrors, a laser, and a detector in a laser assembly.

### BACKGROUND

Multi-pass optical cells are a collection of optics that optical devices, such as laser assemblies, use to extend the optical path of a beam of light. One type of multi-pass cell is a Herriott cell, which generally includes a pair of concave mirrors arranged spaced apart and facing each other to reflect the light beam received from a light source multiple times. The two mirrors, a light source, and a light detector need to be properly aligned to ensure that the light beam has traveled the predetermined optical path. Existing systems may utilize manual mechanical or electronics manipulation, such as a rotational/translational mechanism, to align the light source with an inlet mirror. However, using the rotational/translational mechanism for aligning the light beam source and the mirrors is time-consuming and complex.

### SUMMARY

A system embodiment may include a laser assembly having an optical cell. The cell includes a first mirror defining an inlet opening or multiple openings to facilitate and control the position and angle of an entry of a laser beam or multiple laser beams inside the cell and defining at least one groove extending radially outwardly from a first center hole towards an outer edge of the first mirror. The cell also includes a second mirror defining at least one additional outlet opening to facilitate an exit of the laser beam(s) from the cell, the second mirror defining at least one slot extending radially outwardly from a second center hole 142 towards an outer edge of the second mirror. The cell further includes a center rod, a first mount, and a second mount. The center rod has a first end portion supporting the first mirror and defining at least one first keyway and a second end portion supporting the second mirror and defining at least one second keyway. The first mount is engaged with the first mirror and the first end portion and has at least one key adapted to engage with the at least one first keyway and the at least one groove to suitably align the first mirror. Moreover, the second mount is engaged with second mirror and the second end portion and has at least one protrusion adapted to engage with the at least one second keyway and the slot to suitably align the second mirror.

In other embodiments, a laser assembly may use additional keyways, slots and threads to affix and orient the mirrors to a larger diameter center tube. These embodiments may reduce assembly steps while also eliminating the need for the center rod and the center hole of the mirror. These embodiments may allow for additional optical surface area if the hole is removed or may serve as an additional inlet for a second light source. One embodiment may target a different species of gas with a much shorter optical pathlength requirement that may run down the center of the optical assembly. These embodiments have no center rod and rely instead on a larger diameter tube with cutouts for airflow to clock and align all of the optical systems in place through a series of key ways and threaded features. Having no center rods allows for more optical surface area in order to add a multitude of optical paths with multiple lasers and optical paths enabling changes in dynamic range or additional gas species.

The optical cell design may be used for absorption spectroscopy, where the measurement technique is governed by the Beer-Lambert Law. More specifically, applied tunable diode laser absorption spectroscopy (TDLAS), where a small, low power, and wavelength tunable laser diode is used as the light source and a small photodiode detector is utilized as the light sensor. Advanced spectroscopy techniques, such as Wavelength Modulated Spectroscopy (WMS), may also be applied to enhance the performance of the optical device.

### BRIEF DESCRIPTION OF THE DRAWINGS

The components in the figures are not necessarily to scale, emphasis instead being placed upon illustrating the principals of the invention. Like reference numerals designate corresponding parts throughout the different views. Embodiments are illustrated by way of example and not limitation in the figures of the accompanying drawings, in which:

FIG. 1 depicts a multi-pass cell laser beam spot patterns, according to one embodiment;

FIG. 2A depicts a perspective view of a laser assembly depicting an inlet opening of a first mirror, according to one embodiment;

FIG. 2B depicts a perspective view of a laser assembly depicting an outlet opening of a second mirror, according to one embodiment;

FIG. 3 depicts a sectional view of the laser assembly, according to one embodiment;

FIG. 4 depicts a perspective view of a center rod of the laser assembly, according to one embodiment;

FIG. 5 depicts a front perspective view of the first mirror and a first mount of the laser assembly, according to one embodiment;

FIG. 6 depicts a rear perspective view of the first mirror and the first mount of the laser assembly, according to one embodiment;

FIG. 7 depicts a front perspective view of the second mirror and a second mount of the laser assembly, according to one embodiment;

FIG. 8 depicts a rear perspective view of the second mirror and second mount of the laser assembly, according to one embodiment;

FIG. 9 depicts a front perspective view of a laser diode of the laser assembly, according to one embodiment;

FIG. 10 is a flowchart for a method of aligning mirrors, according to one embodiment depicting how the design of the multi-pass cell is determined;

FIG. 11A is a high-level block diagram of a laser assembly, according to one embodiment;

FIG. 11B is a high-level block diagram for a cell 103 of a laser assembly 101, according to another embodiment of the disclosure;

FIG. 12 depicts a perspective view of one cell assembly that does not use a center rod, according to one embodiment;

FIG. 13 depicts a front perspective view of the first mirror and a first mount of the laser assembly, according to one embodiment;

FIG. 14 depicts a perspective view of the optical cell assembly in which mirrors are aligned and clocked to the center tube using a series of slots and keyways, according to one embodiment;

FIG. 15 depicts a perspective view of the optical cell assembly with additional components for affixing and orienting the light source and light detector to the cell, according to one embodiment;

FIG. 16 is a high-level block diagram of a laser assembly, according to one embodiment, and

FIG. 17 illustrates the laser beam angle into the optical from a perspective of the input mirror according to one embodiment.

### DETAILED DESCRIPTION

The following description is made for the purpose of illustrating the general principles of the embodiments disclosed herein and is not meant to limit the concepts disclosed herein. Further, particular features described herein can be used in combination with other described features in each of the various possible combinations and permutations. Unless otherwise specifically defined herein, all terms are to be given their broadest possible interpretation including meanings implied from the description as well as meanings understood by those skilled in the art and/or as defined in dictionaries, treatises, etc.

The present system allows for the precise and accurate alignment of the various optical components of a multi-pass optical cell. Various features on the optical cell system are included to facilitate the alignment, namely the indexing and rotational position of the entry and exit holes located on the mirrors of the Herriott cell in the desired position while maintaining proper alignment and to control the laser pathlength during an assembly process. Indexing of the mirrors may be accomplished by referencing a center alignment rod used to keep the mirrors a fixed distance apart. The mounts ensure that a laser diode and a light detector affixed to the back of the inlet mirror and outlet mirror, respectively, are fixed at desired angles to ensure proper beam path and optimal light detection. The mounts significantly decrease assembly time and assembly complexity and increase the ease of manufacturing Herriott cells for large-scale productization. The disclosed system and method facilitate an easy alignment of the mirrors, the light source, and the light detector. In some embodiments, there may be a multitude of light sources with varying optical pathlengths, such as CO₂ that may be aligned through another inlet and any combination of outlets.

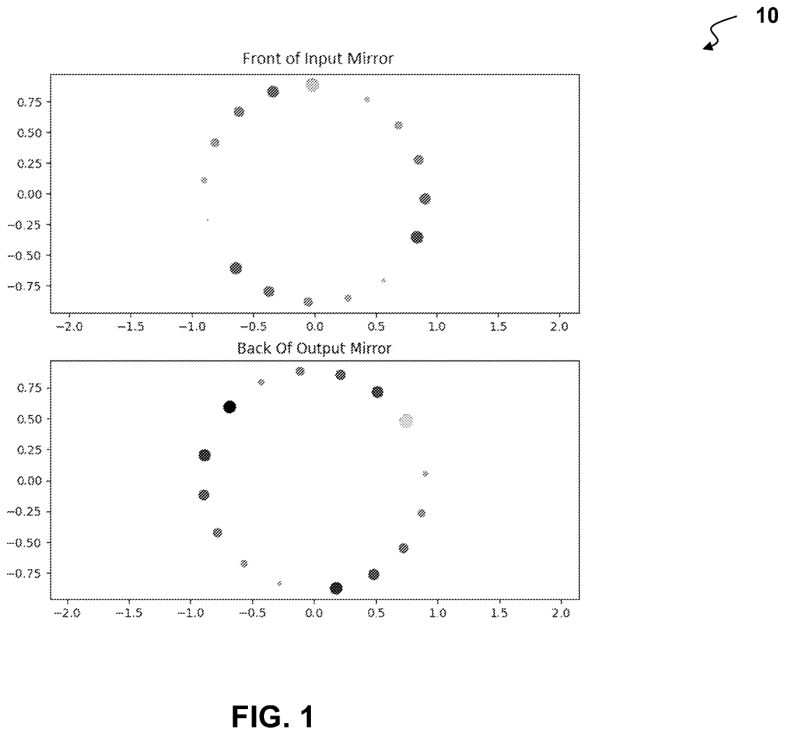

FIG. 1 depicts a multi-pass cell laser beam spot patterns 10. The design of a multi-pass cell laser beam spot pattern can be determined using methods and equations disclosed herein. Spot patterns may result in spot pattern graphs, which depict a Herriott cell spot pattern simulation. The red and blue dots represent the reflection points from the perspective of the front of the “input mirror” and the back of the “output mirror”, respectively. The size and opacity of the dots shown in the simulation visually represent the reflection number, where the opacity and diameter of the spot decrease with each reflection. The entrance hole is indicated by the green dot on the front of the input mirror, the first reflection is represented by the cyan spot on the back of the output mirror, and the exit of the laser beam from the optical cell is indicated by the black dot.

In another embodiment, the indexing of the mirrors may be accomplished by the referencing of an outer alignment tube used to keep the mirrors a fixed distance apart. The mounts ensure that a laser diode and a light detector affixed to the back of the inlet mirror and the outlet mirror, respectively, are fixed at the desired angles to ensure proper beam path and optimal light detection. The mounts significantly decrease assembly time and assembly complexity and increase the case of manufacturing Herriott cells for large-scale productization. The disclosed system and method facilitate an easy alignment of the mirrors, the light source, and the light detector.

All designs facilitate the ease of manufacturing high precision, analytical concentration measurement devices that rely upon multi-pass optical cells for increased light path length. These devices are used to measure gas species concentration through the physical process described by the “Beer-Lambert Law”, which describes how the spectral intensity measured at a specific wavelength after passing through a sample can be used to characterize physical parameters based on an initial spectral intensity and absorption path length:

$$log ( \frac{{I}_{0}}{I} ) = A = ε ℓ c$$

Where,
   A is the absorbance
   ε is the molar attenuation coefficient or absorptivity of the attenuating species
   [symbol] is the optical path length
   c is the concentration of the attenuating species

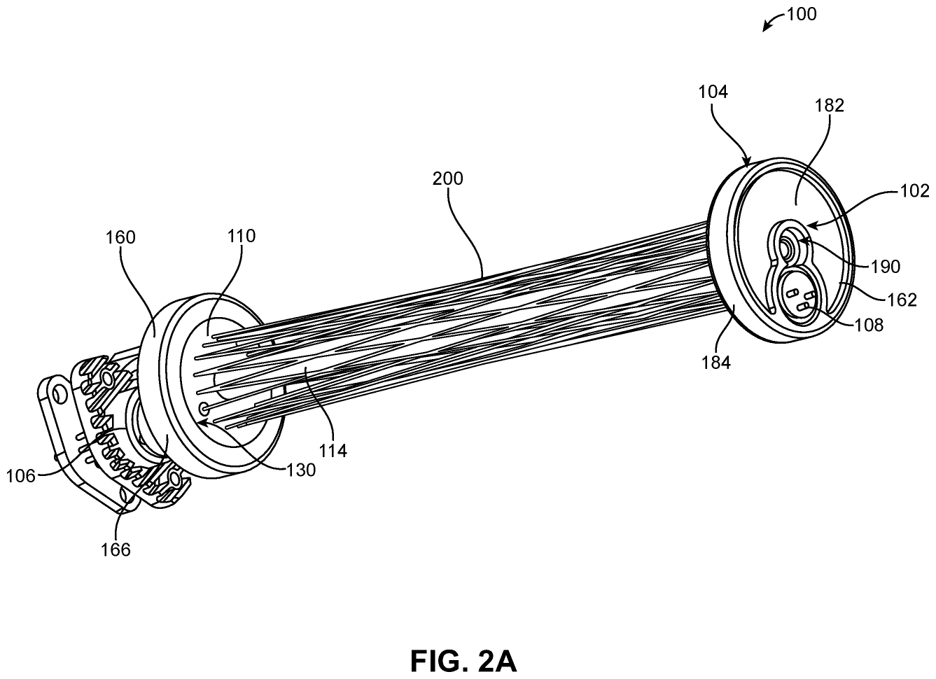

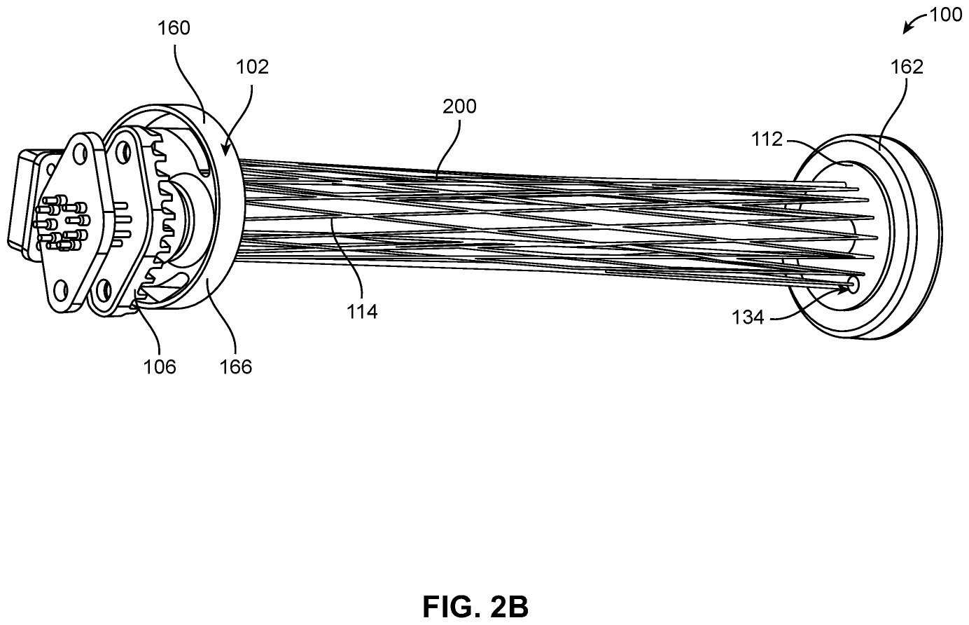

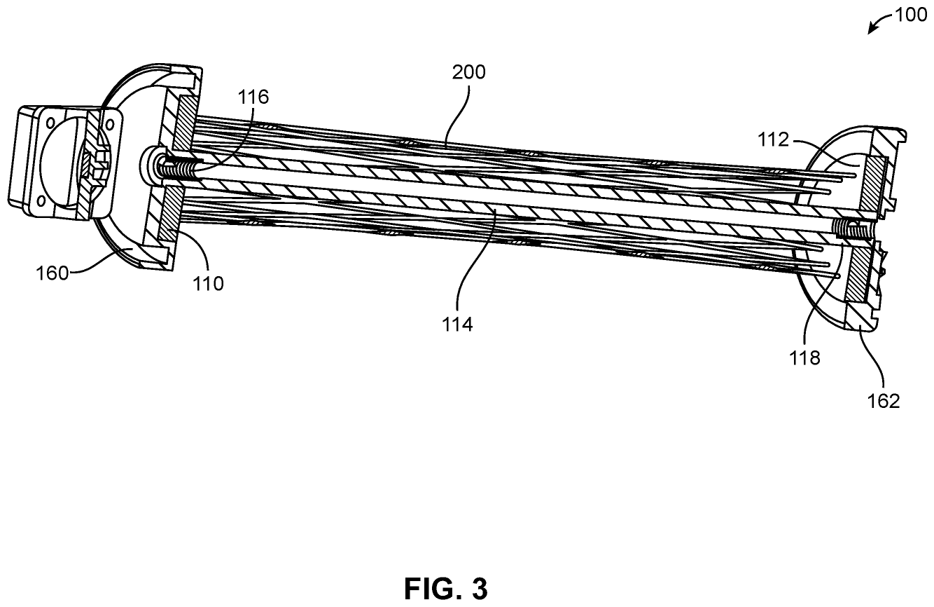

Referring to FIGS. 2A, 2B, and 3, a laser assembly 100 is shown. The laser assembly 100 includes a cell 102, for example, a Herriott cell 104; a laser diode 106 mounted on the cell 102; and a detector 108 mounted on the cell 102. The cell 102 includes one or more mirrors, for example, a first mirror 110 and a second mirror 112. The first mirror 110 is arranged spaced apart and opposite from the second mirror 112. The first mirror 110 is located at a predetermined distance from the second mirror 112.

In one embodiment, the mirrors 110, 112 are spherical mirrors having predetermined radii. The distance between the mirrors 110, 112 and the radii of the mirrors 110, 112 may be selected based on a desired optical path length of a laser beam 200 traveling through the cell 102. The laser diode 106 is adapted to emit the laser beam 200. In one embodiment, the laser beam 200 is an infrared beam.

The cell 102 may further include a center rod 114 extending from the first mirror 110 to the second mirror 112 and engaged to the first mirror 110 and the second mirror 112. In some embodiments, the center rod 114 may be made from a High Strength aluminum 2024. In other embodiments, the center rod 114 may be made from multiple materials such as titanium or a machinable ceramic. In some embodiments, the center rod 114 diameter may be about 7 mm, or roughly 27.5% the size of the mirror diameter. The center rod 114 dimensions may change based on material selected.

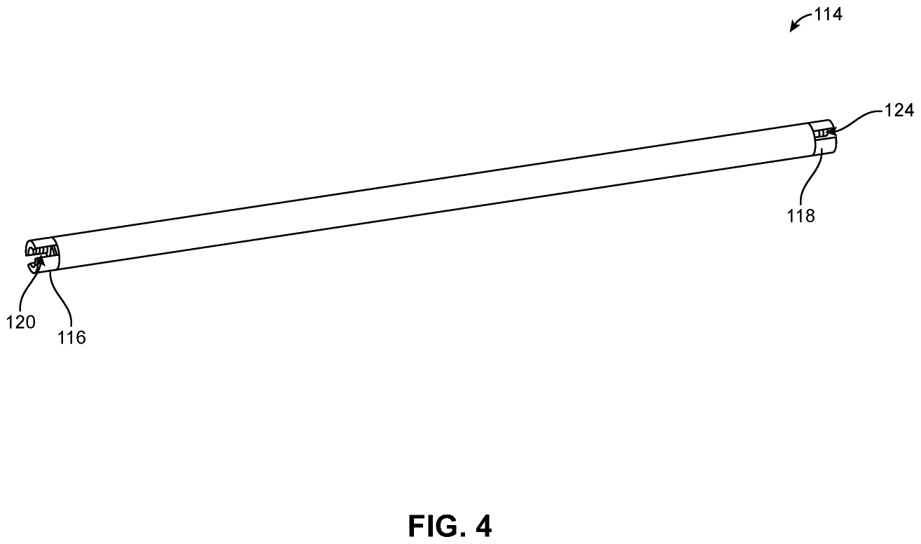

Referring to FIGS. 3 to 4, the center rod 114 may be a hollow rod and may include a first end portion 116 engaged with the first mirror 110 and a second end portion 118 engaged with the second mirror 112. Further, the first end portion 116 defines at least one first keyway 120, for example, two keyways 124, to enable a correct or desired positioning or alignment of the first mirror 110 on the center rod 114. In one embodiment, the two first keyways 120 are arranged diametrically opposite to each other. The first end portion 116 may include any number of first keyways 120.

Similar to the first end portion 116, the second end portion 118 defines at least one second keyway 124, for example, two second keyways 124, to enable a correct or desired positioning or alignment of the second mirror 112 on the center rod 114. In one embodiment, the two keyways 124 are arranged diametrically opposite to each other. The second end portion 118 may define any number of second keyways 124. Further, the first keyways 120 and the second keyways 124 may be disposed at predefined angular orientations from each other to enable the mounting of the mirrors 110, 112 at a desired orientation on the center rod 114 and relative to each other.

The first mirror 110 may include an opening to allow the laser beam 200 to enter inside the cell 102 from the laser diode 106. The second mirror 112 may include an opening to allow the laser beam 200 to exit the cell 102. These openings may be holes, apertures, semi-transparent facets, or the like.

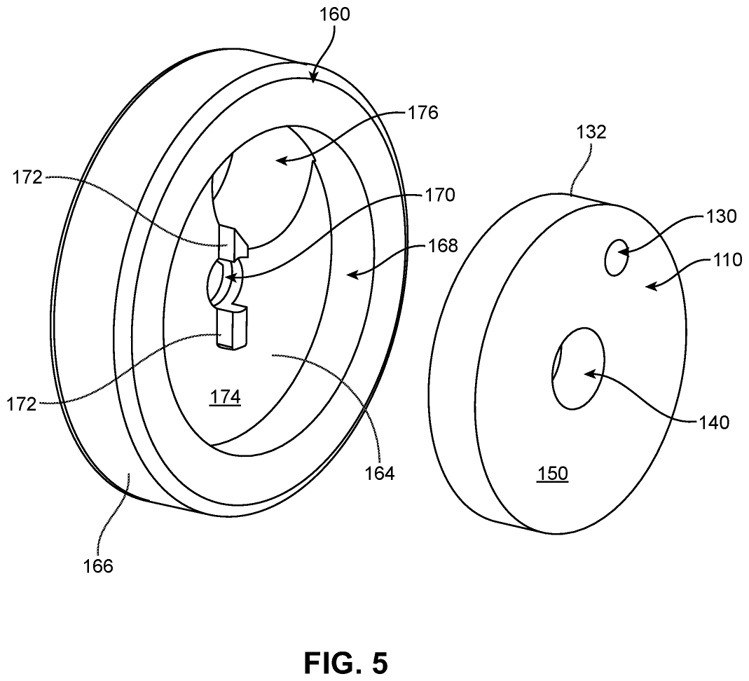

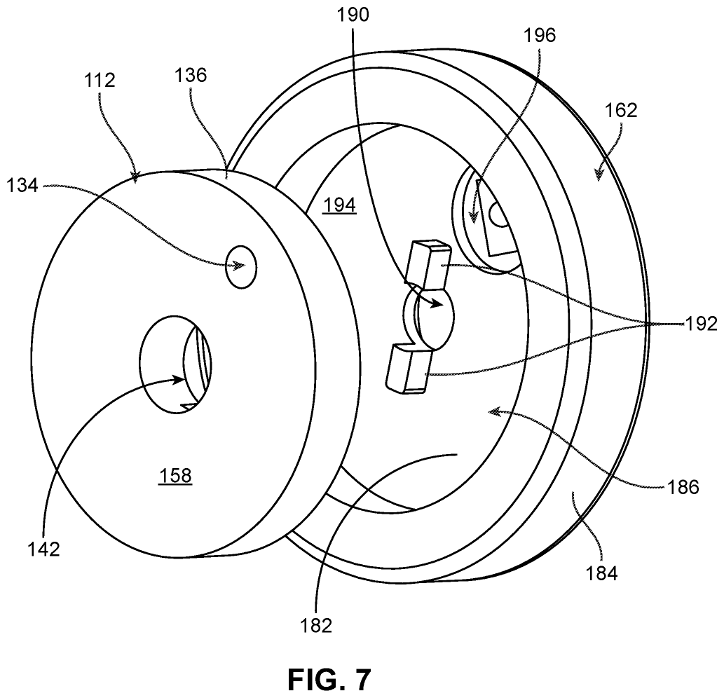

As shown in FIG. 2B and FIG. 5, the first mirror 110 includes an inlet opening 130 arranged proximate to an outer edge 132 of the first mirror 110. As shown in FIG. 1 and FIG. 7, the second mirror 112 includes an outlet opening 134 disposed proximate to an outer edge 136 of the second mirror 112. The laser beam 200, after entering inside the cell 102 through the inlet opening 130, goes through multiple reflections between the first mirror 110 and the second mirror 112, and exits the cell 102 through the outlet opening 134. The number of reflections of the laser beam 200 may depend upon a launch angle of the laser beam 200 and/or an angular orientation/position of the outlet opening 134 with respect to the inlet opening 130. The first keyways 120 and the second keyways 124 enable the correct or desired positioning of the first mirror 110 and the second mirror 112 on the center rod 114, such that the inlet opening 130 and the outlet opening 134 are positioned at a desired angular orientation relative to each other to achieve a desired path length for the laser beam 200.

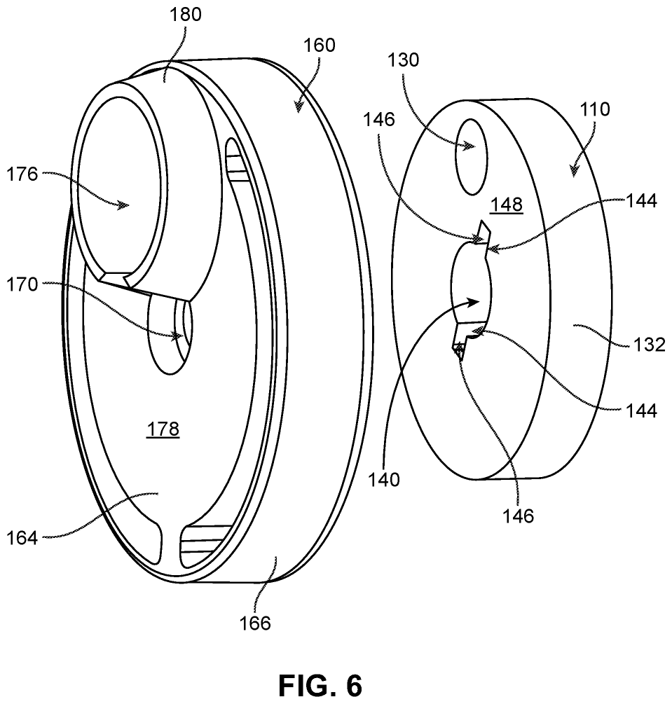

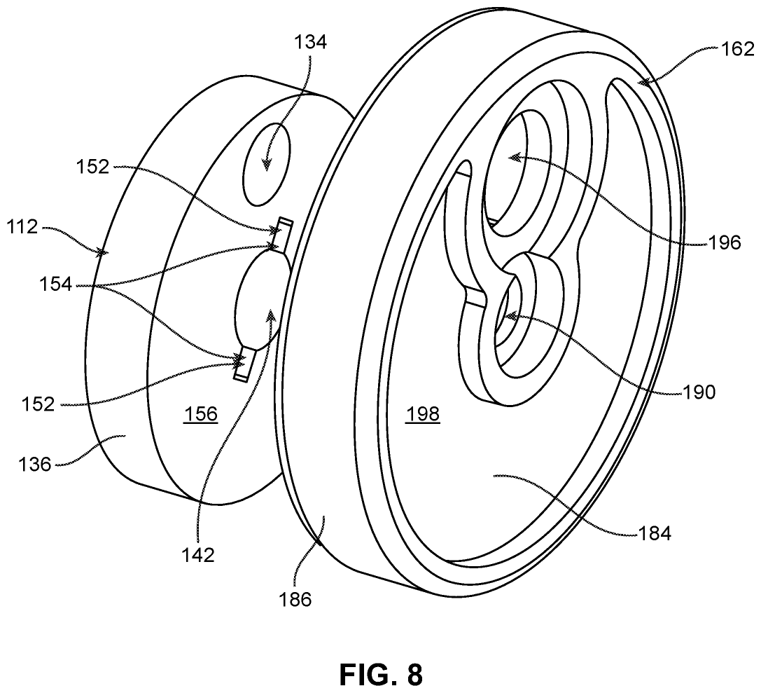

Further, the first mirror 110 includes a first center hole 140 (See FIGS. 5 and 6) to receive the first end portion 116 of the center rod 114, and the second mirror 112 includes a second center hole 142 (See FIGS. 7 and 8) to receive the second end portion 118 of the center rod 114. Referring to FIGS. 5 and 6, the first mirror 110 defines at least one first alignment structure 144 that aligns with the at least one first keyway 120 of the center rod 114 in an assembly of the first mirror 110 with the center rod 114 to position the inlet opening 130 at the desired location. In one embodiment, the at least one first alignment structure 144 includes at least one groove 146, for example, two grooves 146, extending radially outwardly from the first center hole 140. In one embodiment, the two grooves 146 extend radially outwardly from the first center hole 140 and are arranged diametrically opposite to each other. Further, the grooves 146 extend from a rear surface 148 of the first mirror 110 towards a front surface 150 of the first mirror 110 in a longitudinal direction. In an engagement of the first mirror 110 with the center rod 114 and in the correct or desired position or alignment of the first mirror 110 on the center rod 114, the grooves 146 align with the first keyways 120.

Referring to FIGS. 7 and 8, the second mirror 112 defines at least one second alignment structure 152 that aligns with the at least one second keyway 124 of the center rod 114. In an embodiment, the at least one second alignment structure 152 includes at least one slot 154, for example, two slots 154, extending radially outwardly from the second center hole 142 of the second mirror 112. In an embodiment, two slots 154 extend radially outwardly from the second center hole 142 and are arranged diametrically opposite to each other. Further, the slots 154 extend from a rear surface 156 of the second mirror 112 towards a front surface 158 of the second mirror 112 in a longitudinal direction. The front surface 150 of the first mirror 110 is arranged to face the front surface 158 of the second mirror 112. Also, the laser beam 200 is adapted to strike the front surfaces 150, 158 and is reflected by the front surfaces 150, 158 of the mirrors 110, 112. Moreover, in an engagement of the second mirror 112 with the center rod 114 and in the correct or desired position or alignment of the second mirror 112 on the center rod 114, the slots 154 align with the second keyways 124. The alignment of the grooves 146 with the first keyways 120 and the alignment of slots 154 with the second keyways 124 ensure correct or desired angular positioning of the inlet opening 130 relative to the outlet opening 134. In an embodiment, the first end portion 116 extends through the first center hole 140 and may be press fitted with the first mirror 110. The second end portion 118 extends through the second center hole 142 and may be press fitted with the second mirror 112.

Also, to attach the mirrors 110, 112 with the center rod 114 and to retain the mirrors 110, 112 in the correct or desired position/orientation/alignment, the cell 102 includes a pair of mounts, for example, a first mount 160 and a second mount 162. In some embodiments, the mirror 110 is placed into the mirror holder. Then the center rod 114 is introduced to the mirror 110 and mirror holder assembly are affixed together with a single screw that threads into the center rod 114. These steps may be repeated for the second mirror 112. Once this assembly is together, the light detector is introduced and then the light source. Other assembly steps are possible and contemplated. The first mount 160 holds the first mirror 110 and is engaged with the first mirror 110 and the first end portion 116 of the center rod 114, while the second mount 162 holds the second mirror 112 and is engaged with the second mirror 112 and the second end portion 118 of the center rod 114.

In one embodiment, as shown in FIGS. 5 and 6, the first mount 160 includes a base 164 and a flange 166 extending circularly around a central axis of the base 164. The flange 166 is disposed substantially perpendicularly to the base 164 and defines a cavity 168 to receive the first mirror 110. In an assembly, the flange 166 is arranged abutting the outer edge 132 of the first mirror 110, while the base 164 is arranged facing the rear surface 148 of the first mirror 110. In some embodiments, the base 164 may be arranged abutting the rear surface 148 of the first mirror 110.

As shown, the base 164 of the first mount 160 defines a central opening 170 to receive the first end portion 116 of the center rod 114. In an assembly, the central opening 170 aligns with the first center hole 140 of the first mirror 110, and the first end portion 116 extends through the first center hole 140 into the central opening 170. Additionally, to attach the first mount 160 to the first mirror 110 and the center rod 114, the first mount 160 includes at least one key 172, for example, two keys 172, arranged diametrically opposite to each other, extending radially outwardly from the central opening 170 towards the flange 166. Moreover, both keys 172 extend outwardly in a longitudinal direction from a front surface 174 of the base 164. In one assembly, the keys 172 extend inside the grooves 146 of the first mirror 110 and the first keyways 120 of the first end portion 116 of the first center rod 114.

The first mount 160 may include a cutout 176 (hereinafter referred to as first cutout 176) extending from a rear surface 178 of the base 164 to the front surface 174 of the base 164. The first cutout 176 is arranged at a radial offset from the central opening 170 and is arranged such that the first cutout 176 is aligned with the inlet opening 130 of the first mirror 110 in the assembly of the first mount 160 with the first mirror 110 and the center rod 114. In one embodiment, a central axis of the first cutout 176 is disposed obliquely relative to a central axis of the central opening 170 and the first center hole 140. An angle between the central axis of the first cutout 176 and the central axis of the central opening 170 is selected based on a desired launch angle of the laser beam 200 inside the cell 102.

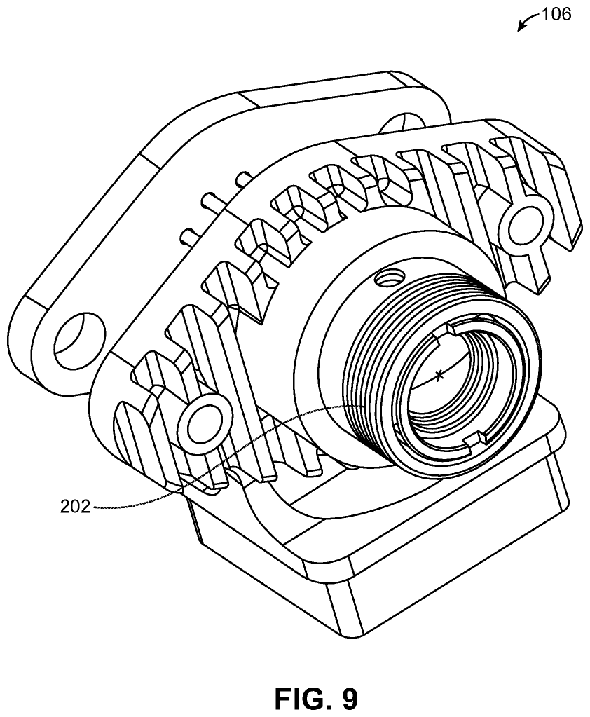

Additionally, the first mount 160 includes a flange portion 180 extending in an accurate manner and around the first cutout 176 to receive an engagement portion 202 (See FIG. 9) of the laser diode 106 to facilitate a coupling and mounting of the laser diode 106 with the first mount 160, and hence the first mirror 110. In one embodiment, the laser diode 106 is in threaded engagement with the flange portion 180, and hence the first mount 160. As shown, the flange portion 180 may include a substantially frustoconical shape and extends outwardly and rearwardly from the rear surface 178 of the base 164. As the first cutout 176 is arranged at a desired orientation relative to the central opening 170, the laser diode 106 is coupled with the first mount 160, and hence with the inlet opening 130 of the first mirror 110, at the desired orientation without requiring complex alignment adjustments.

In one embodiment, as shown in FIGS. 7 and 8, the second mount 162 includes a base 182 and a flange 184 extending circularly around a central axis of the base 182. The flange 184 is disposed substantially perpendicularly to the base 182 and defines a cavity 186 to receive the second mirror 112. In one assembly, the flange 184 is arranged abutting the outer edge 136 of the second mirror 112, while the base 182 is arranged facing the rear surface 156 of the second mirror 112. In some embodiments, the base 182 may be arranged abutting the rear surface 156 of the second mirror 112.

As shown, the base 182 of the second mount 162 defines a central hole 190 to receive the second end portion 118 of the center rod 114. In an assembly, the central hole 190 aligns with the second center hole 142 of the second mirror 112, and the second end portion 118 extends through the second center hole 142 into the central hole 190. Additionally, to attach or engage the second mount 162 to the second mirror 112 and the center rod 114, the second mount 162 includes at least one protrusion 192, for example, two protrusions 192 arranged diametrically opposite to each other, extending radially outwardly from the central hole 190 toward the flange 184. Moreover, both protrusions 192 extend outwardly in a longitudinal direction from a front surface 194 of the base 182. In an assembly, the protrusions 192 extend inside the slots 154 of the second mirror 112 and the second keyways 124 of the second end portion 118 of the center rod 114.

The second mount 162 includes a cutout 196 (hereinafter referred to as second cutout 196) extending from a rear surface 198 of the base to the front surface 194 of the base 182. The second cutout 196 is arranged at a radial offset from the central hole 190 and is arranged such that the second cutout 196 is aligned with the outlet opening 134 of the second mirror 112 in the assembly of the second mount 162 with the second mirror 112 and the center rod 114. The second cutout 196 is adapted to receive the detector 108 and facilitates an engagement of the detector 108 with the second mount 162 and correct or desired alignment or positioning of the detector 108 with the outlet opening 134.

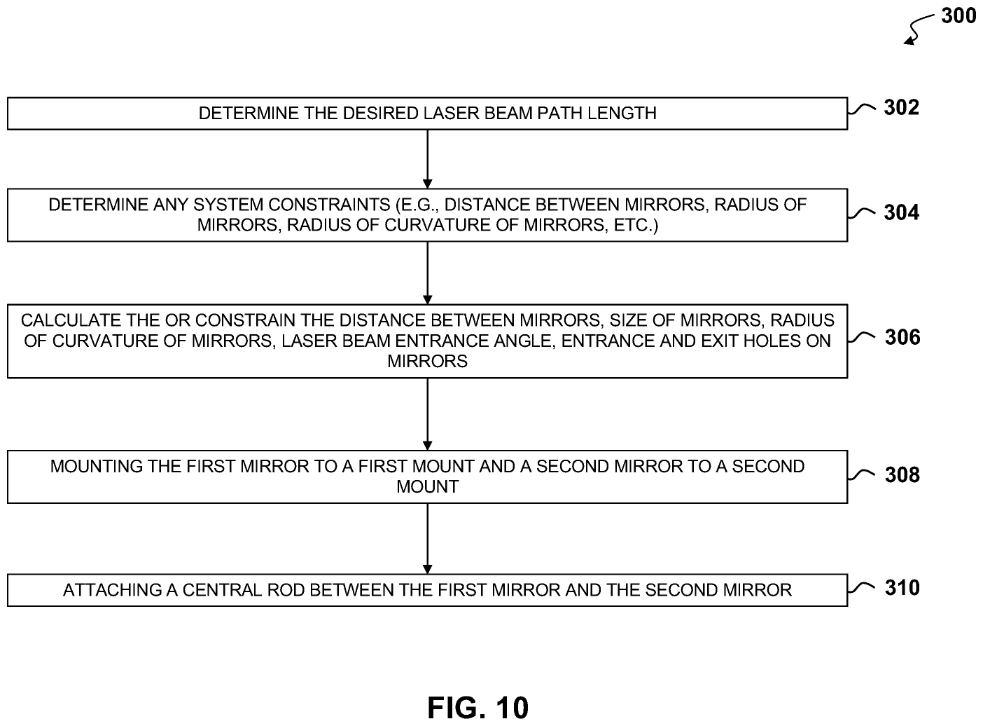

FIG. 10 is a flow chart of a method 300 for aligning mirrors in a cell. The method 300 may include determining a desired laser beam path length (step 302). The method 300 may then include determining system constraints (step 304). The method 300 then proceeds to calculating a distance between system constraints or constraining the distance between system constraints (step 306). The next step is the mounting a first mirror to a first mount and a second mirror to a second mount (step 308). The method 300 may then include attaching a center rod between the first mirror and the second mirror (step 310). The system constraints comprise one or more distances between mirrors, radius of mirrors, radius of curvature of mirrors, laser beam entrance angles, and entrance and exit holes on mirrors.

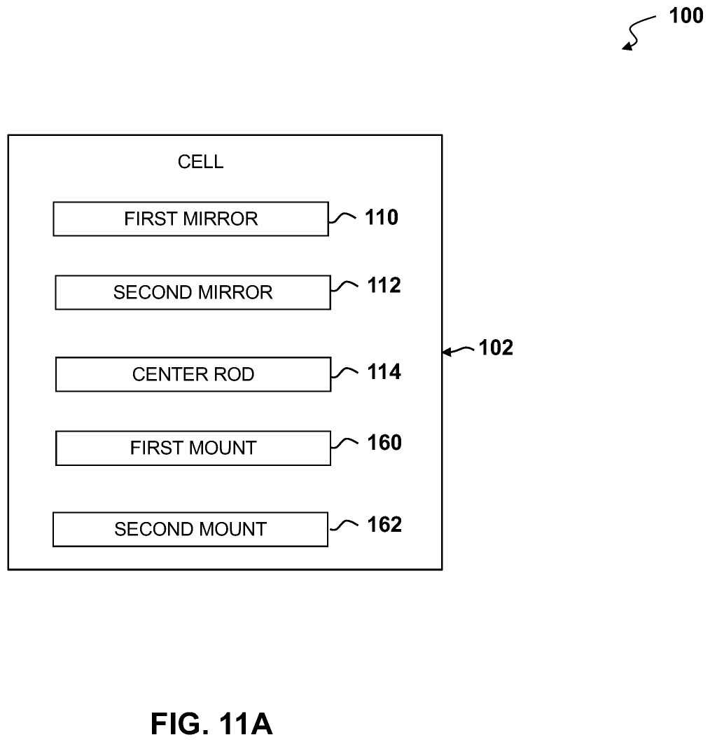

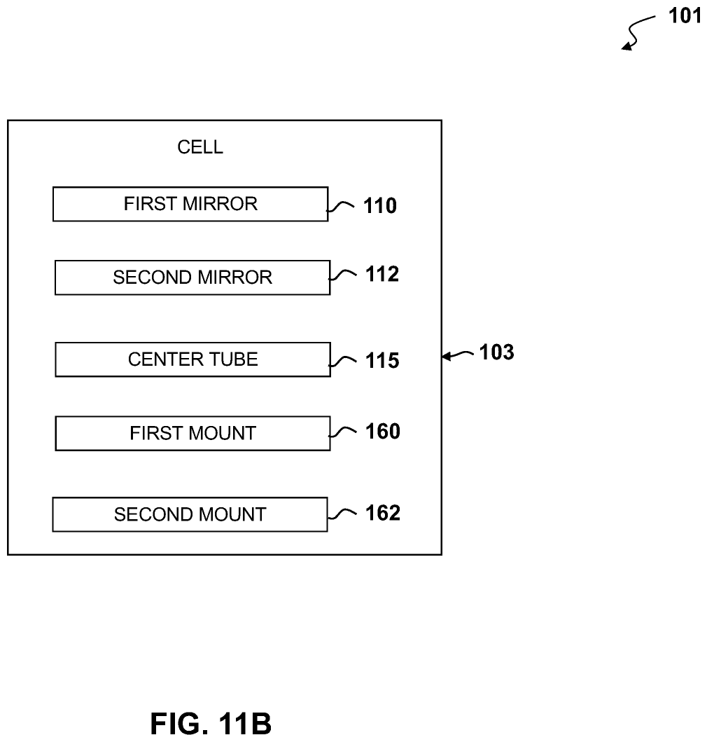

FIG. 11A is a high-level block diagram for a cell 102 of a laser assembly 100, according to an embodiment of the disclosure. The cell 102 includes a first mirror 110, a second mirror 112, a center rod 114, a first mount 160, and a second mount 162.

FIG. 11B is a high-level block diagram 101 for a cell 103 of a laser assembly 101, according to another embodiment of the disclosure. The cell 103 includes a first mirror 110, a second mirror 112, a alignment tube 115, a first mount 160, and a second mount 162.

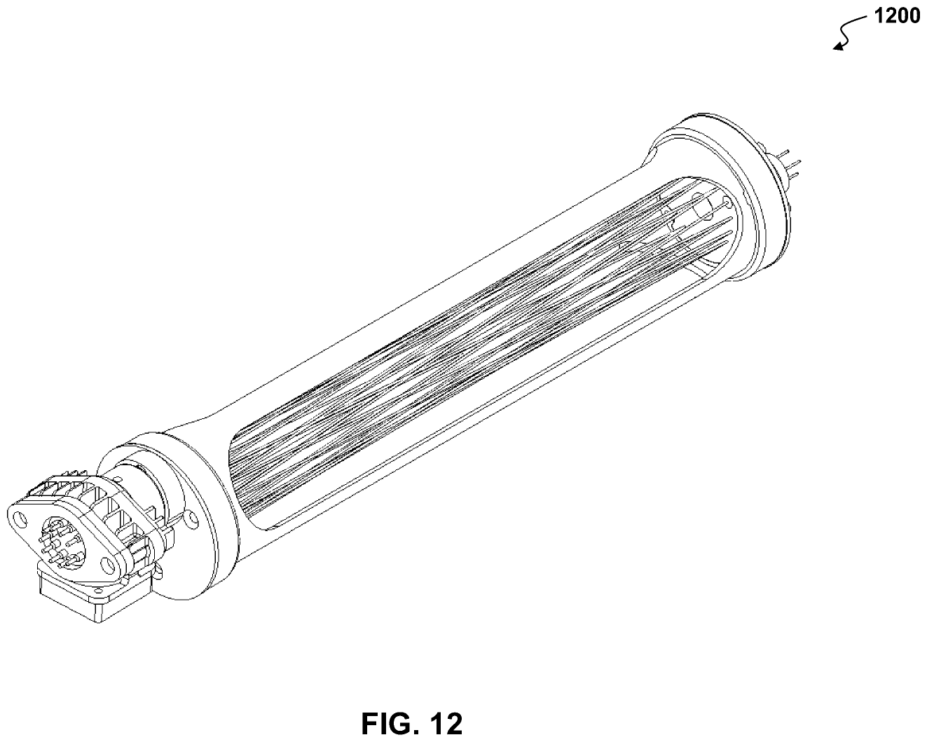

FIG. 12 depicts a perspective view of one cell assembly 1200 that does not use a center rod, according to one embodiment. The cell assembly 1200 includes cutouts in the tubes for airflow, patterned cuts in mirrors, and mirror mounts. In one embodiment, the mirror mounts may be replaced with features machined directly into the mirrors. Keyways may be added to the outer diameter and threads or threaded inserts may be added in the back surface of the mirrors. In some embodiments, the cell assembly 1200 may include a different material or shape of the alignment tube.

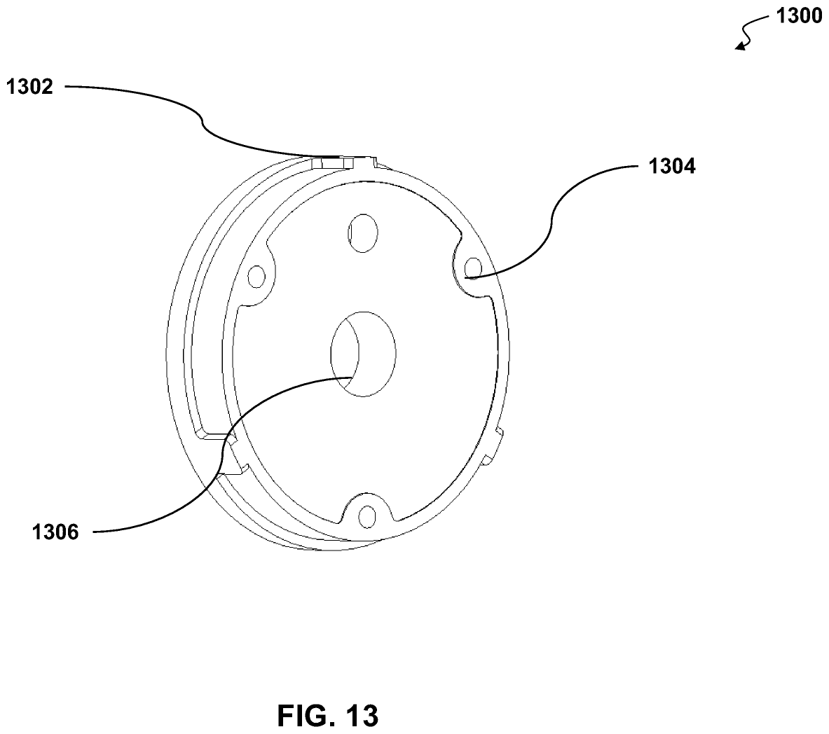

FIG. 13 depicts a front perspective view of the first mirror and a first mount of the laser assembly 1300, according to one embodiment. The features of the first mirror and a first mount of the laser assembly 1300 include: a locating feature 1302, a location feature 1304, and a hole 1306. The locating feature 1302 may locate the mirror to the alignment tube 115 in the desired orientation. The locating feature 1304 may be a cutout in the mirror that orients the mirror in the desired orientation to the mounting bracket so that the mirrors are clocked at the desired angle when assembled to alignment tube. The hole 1306 may serve as a passthrough for a different optical paths with shorter pathlength requirements.

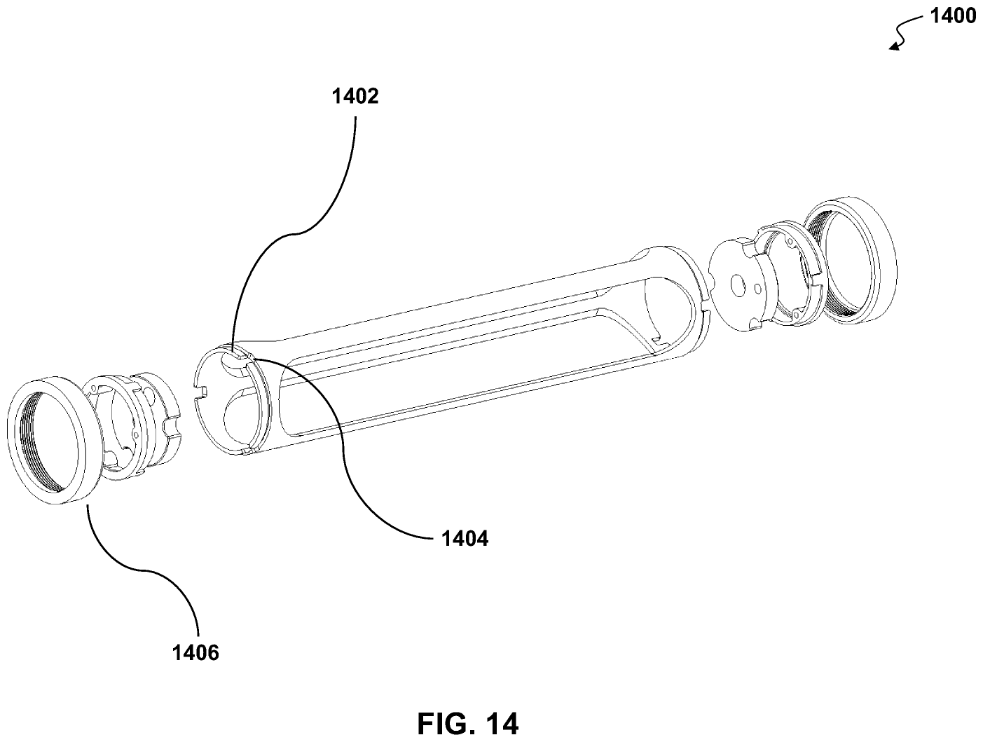

FIG. 14 depicts a perspective view of the optical cell assembly 1400 in which mirrors are aligned and clocked to the alignment tube 115 using a series of slots and keyways, according to one embodiment. The features of the optical cell assembly 1400 include: a threaded feature 1402, a locating feature 1404, and a collar 1406. The threaded feature 1402 may receive the collar 1406. The locating feature 1404 may receive the mirror and clock it at the desired angle. The collar 1406 may affix the mirror to the alignment tube.

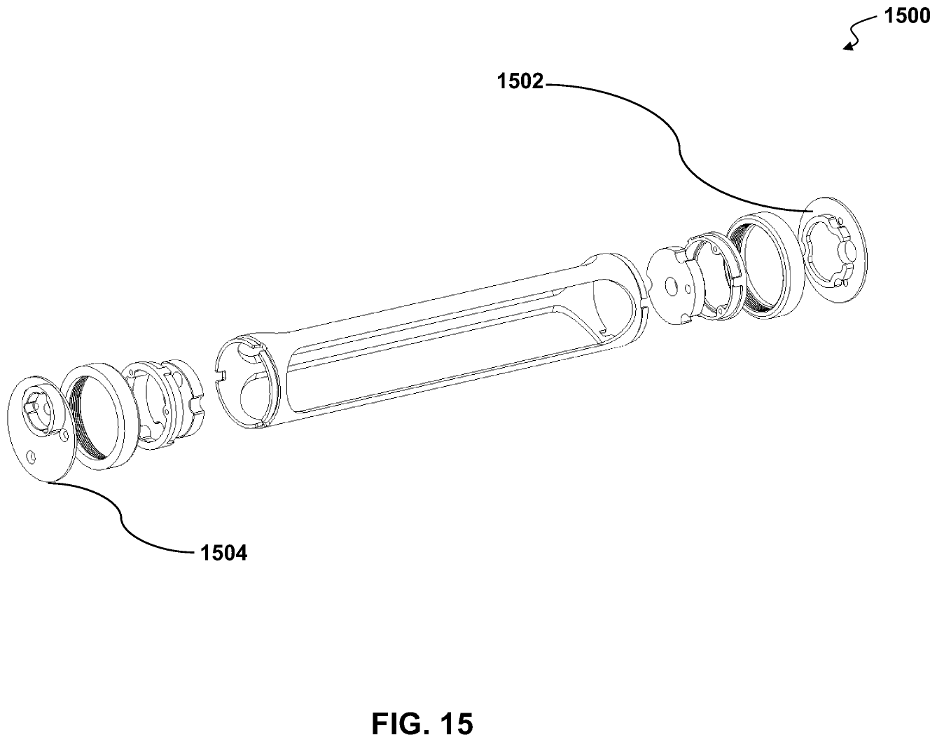

FIG. 15 depicts a perspective view of the optical cell assembly 1500 with additional components for affixing and orienting the light source and light detector to the cell, according to one embodiment. Features of the optical cell assembly 1500 include: a detector alignment plate 1502 and a laser alignment plate 1504. The detector alignment plate 1502 may be affixed with several screws to the back of the mirror. The laser alignment plate 1504 may have a keyed channel for installation of the laser source at the desired inlet angle. The laser alignment plate 1504 may be affixed with several screws to the back of the mirror assembly.

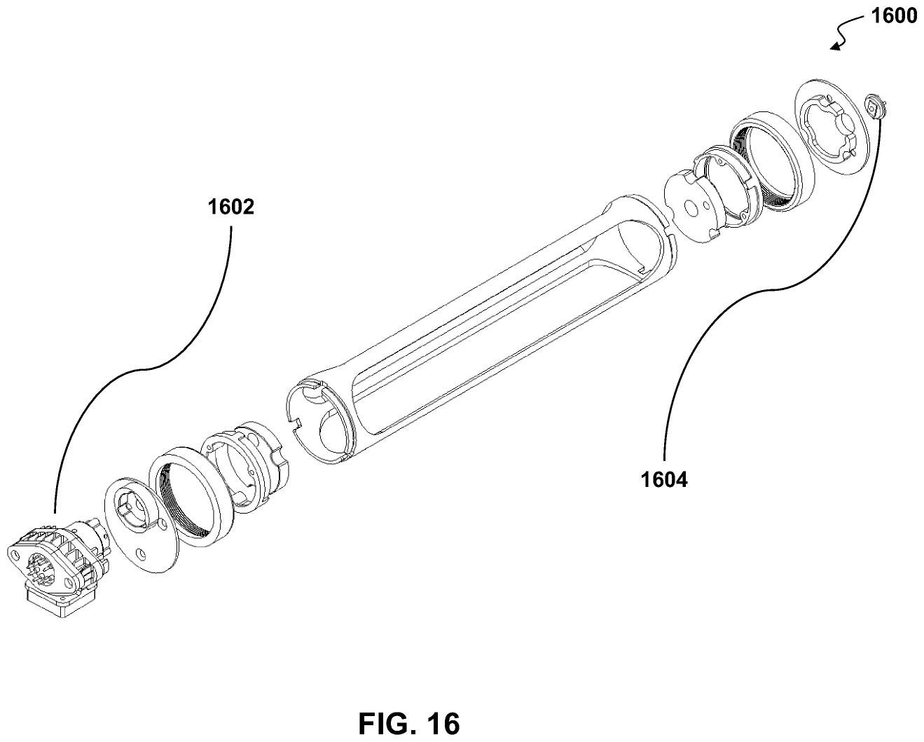

FIG. 16 is a high-level block diagram of a laser assembly 1600, according to one embodiment. Features of the laser assembly 1600 include: an introduction of the collimated laser assembly to the Herriot cell assembly 1602; and an introduction of the light detector to the Herriot cell assembly 1604.

Additional embodiments as described in FIG. 12 through FIG. 16 may be comprised of a laser assembly that uses additional keyways, slots and threads to affix and orient the mirrors to a larger diameter alignment tube 115 as called out in FIG. 13 and FIG. 14. These embodiments reduce assembly steps while also eliminating the need for the center rod and the center hole of the mirror. This assembly allows for additional optical surface area if the hole is removed or a multitude or may serve as an additional inlet for a second light source. One embodiment may target a different species of gas with much shorter optical pathlength requirements that may run down the center of the optical assembly. These embodiments have no center rod and rely instead on a larger diameter tube with cutouts for airflow to clock and align all of the optical systems in place through a series of keyways and threaded features. Having no center rods allows for more optical surfaces in order to add a multitude of optical paths with multiple lasers and optical paths enabling changes in dynamic range or additional gas species.

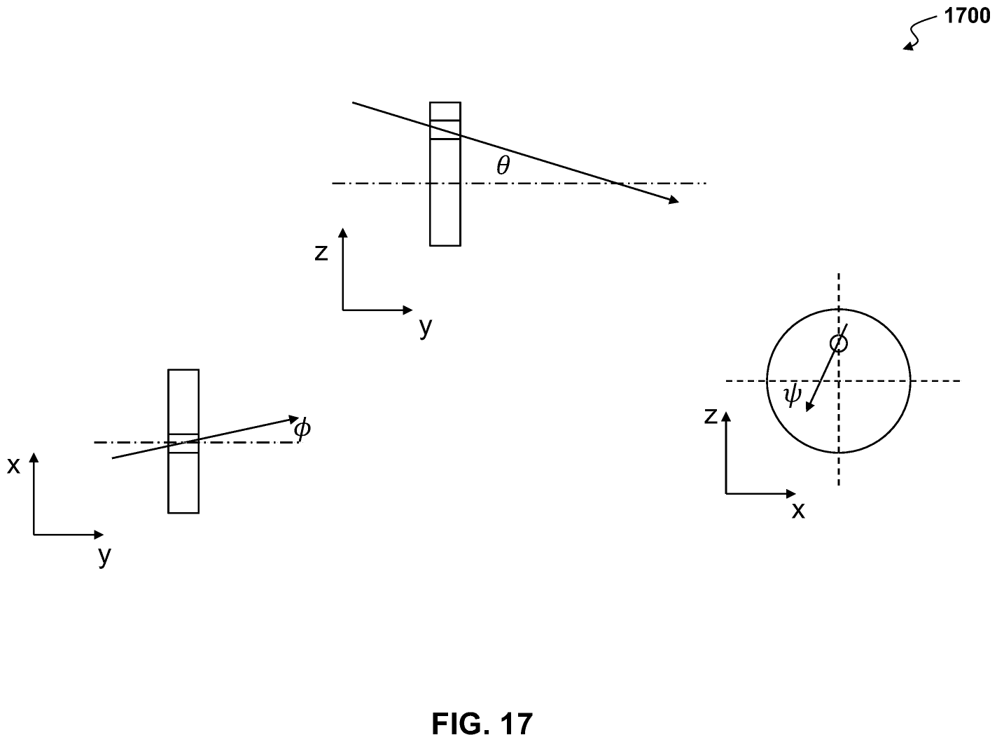

FIG. 17 illustrates the laser beam angle into the optical from a perspective of the input mirror according to one embodiment 1700. The entrance hole is indicated by a rectangle (cross sectional view of mirror) in two images and a circle in one. The mirror is represented by a rectangle in two images (cross sectional view of mirror) and a circle in one. Ray projections are depicted as arrows of the laser beam. Where theta is the angle between the laser beam vector and the y axis in the zy plane, phi is the angle between the laser beam vector and the y-axis in the xy plane, and psi is the angle between the laser beam vector and the x-axis in the zx plane.

It is contemplated that various combinations and/or sub-combinations of the specific features and aspects of the above embodiments may be made and still fall within the scope of the invention. Accordingly, it should be understood that various features and aspects of the disclosed embodiments may be combined with or substituted for one another in order to form varying modes of the disclosed invention. Further, it is intended that the scope of the present invention herein disclosed by way of examples should not be limited by the particular disclosed embodiments described above.

1. A laser assembly comprising:
a cell comprising:
a first mirror, the first mirror comprising:
an inlet opening disposed in the first mirror to facilitate an entry of a laser beam inside the cell; and
at least one groove extending radially outwardly from a first center hole towards an outer edge of the first mirror;
a second mirror, the second mirror comprising:
an outlet opening disposed in the second mirror to facilitate an exit of the laser beam from the cell; and
at least one slot extending radially outwardly from a second center hole towards an outer edge of the second mirror;
a center rod, the center rod comprising:
a first end portion configured to support the first mirror and defining at least one first keyway; and
a second end portion configured to support the second mirror and defining at least one second keyway;
a first mount configured to engage the first mirror and the first end portion, wherein the first mount comprises at least one key adapted to engage the at least one first keyway and the at least one groove to align the first mirror; and
a second mount configured to engage the second mirror and the second end portion, wherein the second mount comprises at least one protrusion adapted to engage with the at least one second keyway and the slot to align the second mirror.

2. The laser assembly of claim 1, wherein the first mount comprises a cutout arranged radially offset from a central opening, wherein the cutout is adapted to receive the first end portion of the center rod and a flange portion extending around the cutout.

3. The laser assembly of claim 2, further comprising:
a laser diode configured to engage with the first mount, wherein an engagement portion of the laser diode extends inside the flange portion and engages the flange portion.

4. The laser assembly of claim 2, wherein a central axis of the cutout is arranged obliquely relative to a central axis of the central opening.

5. The laser assembly of claim 1, further comprising:
a detector mounted on the second mount and adapted to receive the laser beam exiting the outlet opening.

6. The laser assembly of claim 1, wherein the first end portion extends through the first center hole of the first mirror and is arranged inside the first center hole such that the at least one groove aligns with the at least one first keyway.

7. The laser assembly of claim 1, wherein the second end portion extends through the second center hole of the second mirror and is arranged inside the second center hole such that the at least one slot aligns with the at least one second keyway.

8. The laser assembly of claim 1, wherein the first end portion includes one or more first keyways, and wherein the second end portion includes one or more second keyways.

9. The laser assembly of claim 1, wherein the first keyways and the second keyways are disposed at predefined angular orientations from each other to enable mounting of the mirrors at a desired orientation on the center rod and relative to each other.

10. A laser assembly comprising:
a cell comprising:
a first mirror;
a second mirror;
a center tube;
a first mount configured to engage the first mirror; and
a second mount configured to engage the second mirror;
wherein a diameter of the center tube comprises cutouts for airflow to clock and align optical systems of the cell through one or more of: slots, keyways, and threaded features.

11-15. (canceled)

16. The laser assembly of claim 10, wherein an indexing of the first mirror and the second mirror is accomplished by referencing of an outer alignment tube used to keep the first mirror and the second mirror a fixed distance apart, wherein the first mount and the second mount ensure that a laser diode and a light detector are affixed to a back of an inlet mirror, the first mirror, an outlet mirror, and the second mirror, respectively, are fixed at desired angles to ensure proper beam path and optimal light detection.

17. (canceled)

18. The laser assembly of claim 10, wherein the cell further comprises:
two first keyways that are configured to be arranged diametrically opposite to each other;
a first end portion that is configured to include any number of first keyways;
two second keyways that are configured to be arranged diametrically opposite to each other; and
a second end portion that is configured to include any number of second keyways.

19-20. (canceled)

21. A method comprising:
engaging a first mirror via a first mount;
engaging a second mirror via a second mount;
engaging a first end portion of a center rod via the first mount; and
engaging a second end portion of the center rod via the second mount;
wherein the first mount and the second mount align the first mirror and the second mirror.

22. The method of claim 21, wherein engaging the first end portion of the center rod via the first mount further comprises:
engaging at least one first keyway and at least one groove via at least one key of the first mount.

23. The method of claim 22, wherein engaging the second end portion of the center rod via the second mount further comprises:
engaging at least one second keyway and a slot via at least one protrusion of the first mount.

24. The method of claim 21, wherein the first mount and the second mount align the first mirror and the second mirror through one or more of: slots, keyways, and threaded features.

25. The method of claim 24, wherein engaging the first end portion of the center rod via the first mount further comprises:
locating the first mirror to the center rod in a desired orientation via a first locating feature;
orienting the first mirror in a desired orientation to the first mount via a second locating feature and a cutout in the first mirror;
clocking the mirrors in the desired orientation when assembled to an alignment tube.

26. The method of claim 24, further comprising:
receiving the first mirror and the second mirror via a locating feature
clocking the first mirror and the second mirror at an angle via the locating feature; and
affixing the first mirror and the second mirror to an alignment tube via a collar.

27. The method of claim 24, further comprising:
affixing a detector alignment plate to a back of a first mirror assembly; and
affixing a laser alignment plate to the back of a second mirror assembly, wherein the laser alignment plate is configured to install a laser source at a desired inlet angle.

28. The method of claim 24, further comprising:
indexing the first mirror and the second mirror by referencing an outer alignment tube used to keep the first mirror and the second mirror a fixed distance apart.
